(19) United States
(12) Patent Application Publication
(10) Pub. No.: US 2022/0406736 A1
(43) Pub. Date: Dec. 22, 2022

(54) HIGH-PERMEABILITY THIN FILMS FOR INDUCTORS IN GLASS CORE PACKAGING SUBSTRATES

(71) Applicant: Intel Corporation, Santa Clara, CA (US)

(72) Inventors: Brandon C. Marin, Gilbert, AZ (US); Srinivas Pietambaram, Chandler, AZ (US); Suddhasattwa Nad, Chandler, AZ (US); Jeremy Ecton, Gilbert, AZ (US)

(73) Assignee: Intel Corporation, Santa Clara, CA (US)

(21) Appl. No.: 17/352,726

(22) Filed: Jun. 21, 2021

(51) Int. Cl. H01L 23/64; H01L 23/15; H01L 23/48; H01L 49/02; H01L 21/768

(52) U.S. Cl. CPC H01L 23/645; H01L 23/15; H01L 23/481; H01L 28/10; H01L 21/76898

(57) ABSTRACT

Disclosed herein are high-permeability magnetic thin films for coaxial metal inductor loop structures formed in through glass vias of a glass core package substrate, and related methods, devices, and systems. Exemplary coaxial metal inductor loop structures include a high-permeability magnetic layer within and on a surface of a through glass via extending through the glass core package substrate and a conductive layer on the high-permeability magnetic layer.

### BACKGROUND

The integrated circuit industry is continually striving to produce ever faster, smaller, and more efficient integrated circuit devices, packages, and systems for use in various electronic products, including, but not limited to, client devices inclusive of portable client devices, desktop client devices, server devices, and the like.

In current integrated circuit packages and related products, increasing power delivery is a critical need, particularly in server and client products. Power delivery efficiency can be increased by incorporating inductive structures into the package core. However, there is an ongoing need to improve the inductive structures by increasing inductance in the inductive core structures. It is with respect to these and other considerations that the present improvements have been needed. Such improvements may become critical as the desire to provide improved integrated circuit devices, packages, and systems becomes more widespread.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following detailed description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings and/or schematics, such that the advantages of the present disclosure can be more readily ascertained, in which:

FIG. 1 illustrates a cross-sectional view of an example assembly including example coaxial metal-inductor loop structures in a glass core package substrate;

FIG. 2 illustrates a flow diagram of an example process for fabricating coaxial metal-inductor loop structures in a glass core substrate

FIGS. 3A, 4A, 6A, 7A, 8A, 9A, and 10 illustrate cross-sectional side views of example assembly structures as particular fabrication operations in FIG. 2 are performed;

FIGS. 3B, 4B, 6B, 7B, 8B, and 9B illustrate top-down views of the example assembly structures of FIGS. 3A, 4A, 6A, 7A, 8A, and 9A;

FIG. 9C illustrates a second cross-sectional side view of the example assembly structure of FIGS. 9A and 9B;

FIG. 5 illustrates an exemplary deposition of a magnetic alloy on exposed glass in a through glass via; and

FIG. 11 is a functional block diagram of an electronic or computing device, all arranged in accordance with at least some implementations of the present disclosure.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers. One layer “on” another layer is in direct contact with the other layer absent any intervening layers.

The term “package” generally refers to a self-contained carrier of one or more dies, where the dies are attached to a package substrate, electronic substrate, or printed circuit board, and may be encapsulated for protection, with integrated or wire-bonded interconnects between the dies and leads, pins or bumps located on the external portions of the package substrate. The package may contain a single die, or multiple dies, providing a specific function. The package is usually mounted on a printed circuit board for interconnection with other packaged integrated circuits and discrete components, forming a larger circuit. The term “electronic substrate” refers to any type of substrate to which a single die or multiple dies may be attached and thereby integrated into an assembly or package. An electronic substrate is inclusive of a printed circuit, a package substrate, interposer or other substrate and may include any sort of such substrates including cored or coreless substrates. Here, the term “printed circuit board” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “core” generally refers to a substrate of an integrated circuit package built upon a core comprising a non-flexible stiff material. Typically, the core has vias extending from one side to the other, allowing circuitry on one side of the core to be coupled directly to circuitry on the opposite side of the core. The core may also serve as a platform for building up layers of conductors and dielectric materials.

Here, the term “dielectric” generally refers to any number of non-electrically conductive materials. For purposes of this disclosure, dielectric material may be incorporated into an integrated circuit package as layers of laminate film or as a resin molded over integrated circuit dies mounted on the substrate and/or in other devices as layers or portions of such components.

Here, the term “metallization” generally refers to metal layers formed over and through the dielectric material of the electronic substrate. The metal layers are generally patterned to form metal structures such as traces and bond pads. The metallization of a package substrate may be confined to a single layer or in multiple layers separated by layers of dielectric. The term “electrode” generally refers to a metal or other conductor that couples to a electronic element such as a resistive element, a capacitive element, etc. An electrode may extend to and contact another metal or conductor or to another electronic element. The term “pad” generally refers to metallization structures that terminate integrated traces, vias, etc. of an electronic substrate.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner The term “predominantly” indicates a material has more than 50% (by weight) of the component. The term “pure” or “substantially pure” indicates a material has more than 99% (by weight) of the component.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Electronic devices, apparatuses, computing platforms, and methods are described below related to high-permeability magnetic thin film materials for inductors in glass core packaging substrates.

As described above, increased power delivery is a need in integrated circuit packages including client devices, server devices, etc. In some embodiments, magnetic materials are integrated into the power delivery architectures as part of inductor structures in a package core of the device. Such magnetic material integration is needed for increased power delivery in such devices (e.g., server products, client products, etc.). Notably, power delivery efficiency is increased by employing magnetic materials that encase plated through holes (i.e., metallization in the through holes) in the package core to create inductive structures in the package. Such inductor structures may be characterized as coaxial metal-inductor loop (MIL) inductors. To increase inductance in such inductor structures, arrays of cylindrical coaxial MIL structures may be used (e.g., linked in series) such that each cylindrical coaxial MIL structure is within a through hole of the package core.

Furthermore, inductance of each of the cylindrical coaxial MIL structures (e.g., in each through hole) may be increased by increasing its height by correspondingly increasing the height of the package core (e.g., from 1 mm to 2 mm), increasing the permeability (μ) of the magnetic material employed in the cylindrical coaxial MIL structure, increasing the conductive material (e.g., copper) thickness on the wall of the cylindrical coaxial MIL structures, and increasing the volume of the magnetic material in the cylindrical coaxial MIL structure. However, increasing the height of the package core has drawbacks as there are limits in z-height that can be employed in the device and there is a continual drive to reduce the z-height so smaller, more efficient devices may be produced. Similarly, increasing the conductive material thickness and/or the thickness of the magnetic material leads to an increased footprint of each cylindrical coaxial MIL structure, which limits inductance density per unit are of the package core and can undesirably consume area that may be otherwise used by the device.

In some embodiments, the use of a wet-deposited high permeability magnetic material alloy on glass techniques are used to improve the permeability of the magnetic material in the cylindrical coaxial MIL structure for use in glass core packaging substrates. For example, the wet-deposition provides electroless deposition of the magnetic layer. Notably the techniques discussed herein may deposit or plate high permeability magnetic material selectively on exposed glass in through glass vias (TGV) formed in the glass core packaging substrate. Furthermore, such techniques may be performed at temperatures (e.g., about 300° C.) not suitable for organic package substrates. The techniques discussed herein deploy supramolecular precursors such as coordination complexes that include a central atom of the desired magnetic alloy materials (e.g., a supramolecular precursor may be deployed for each of the alloy materials such as two supramolecular precursors for binary alloys, three supramolecular precursors for ternary alloys, and so on) surrounded by a number of ligands (e.g., bound molecules or ions) that have a high affinity to glass. For example, the supramolecular precursors may be provided in a solution and the supramolecular precursors may coat the exposed glass. Using heat treatment such as thermal processing at a temperature of about 300° C., a high permeability alloy is formed (and the solution and ligands are driven off).

The high permeability alloy is deployed in a cylindrical coaxial MIL structure that includes the high permeability magnetic alloy within a TGV of the glass core and on a sidewall thereof and a conductive material (e.g., metallization) within the TGV an on the high permeability magnetic alloy. The conductive material further extends from an interconnect on a first side of the glass core to an interconnect on a second side of the glass core. The interconnect may be a pad or lid of the cylindrical coaxial MIL structure, a trace or line of metallization, a build up metallization layer, or the like. The high permeability magnetic alloy is a solid or solid state material (e.g., not within another material matrix such as an epoxy) and is a substantially pure alloy having not less than 99% of the two or more materials that make up the alloy. Notably, in some embodiments, portions of the ligands may advantageously remain in the magnetic alloy. For example, the substantially pure alloy may include the materials of the alloy and carbon from the ligands. Furthermore, the substantially pure alloy may be a mixture of metallic phases (e.g., two or more solutions, each forming a microstructure of different crystals within the alloy).

As discussed, in some embodiments, the techniques discussed herein use wet-deposited high permeability alloy on glass for cylindrical coaxial MIL structures in glass core packaging substrates. The wet-deposition uses magnetic supramolecular precursors for self-assembled high-permeability thin films in glass architectures. Since the ligands have a selective affinity for glass, they are suited for deployment in contexts that use a glass core as the primary core substrate. The use of such high permeability magnetic alloys in cylindrical coaxial MIL structures in glass core packaging substrates increase inductance, and increase performance particularly in server devices. Such improvements are provided without drawbacks such as increased z-height and increased footprint.

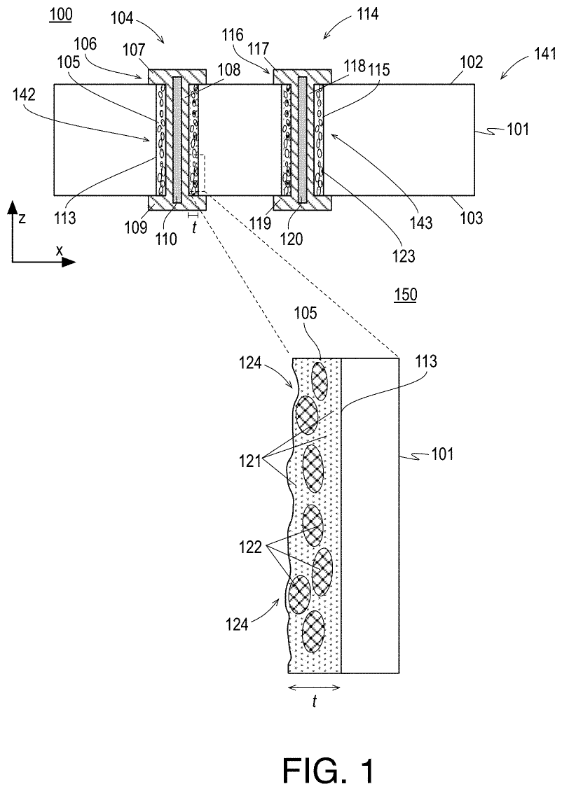

FIG. 1 illustrates a cross-sectional view of an example assembly 100 including example coaxial metal-inductor loop structures 104, 114 in a glass core package substrate 141, arranged in accordance with at least some implementations of the present disclosure. As shown, glass core package substrate 141 includes a glass core 101, in which inductor structures 104, 114 are formed. Glass core 101 may further provide a core for build up layers of interconnect metallization, a core for mounting to a printed circuit board such as a motherboard, as a host for any number of integrated circuit (IC) dies, and so on. Furthermore, glass core package substrate 141 may include any number of other devices therein or thereon inclusive of capacitors, embedded electronic devices, and so on. In some embodiments, glass core package substrate 141 may be characterized as a package substrate 141 including a glass core 101.

Glass core 101 may include any suitable material or materials. In some embodiments, glass core includes borosilicate glass. In some embodiments, glass core includes fused silica (e.g., quartz). In some embodiments, glass core includes sapphire. Glass core package substrate 141 may be deployed in any context in assembly 100 inclusive of glass substrate contexts, interposer contexts, package core contexts, and others. Notably, inductor structures 104, 114 may be deployed for power delivery to an IC die (not shown) coupled to inductor structures 104, 114 and glass core package substrate 141. Such power delivery may be routed to the IC die from a printed circuit board (not shown) on which glass core package substrate 141 is mounted or from another source.

As shown, inductor structure 104 includes a magnetic layer 105 within a through glass via (TGV) 142 formed in glass core 101. Through glass via 142 extends from a front side 102 (or surface) to a back side 103 (or surface) of glass core 101. Through glass via 142 may have any suitable z-height and glass core 101 may have any suitable thickness such as a z-height/thickness in the range of 0.5 to 3.0 mm Through glass via 142 may also have any suitable width (e.g., critical dimension) such as a width in the range of 20 to 200 μm. Although illustrated with through glass via 142 having a vertical sidewall surface (e.g., through glass via 142 being substantially cylindrical), in some embodiments through glass via 142 may have taper such that it has a wider opening at front side 102 than at back side 103. Any suitable taper may be deployed such as a taper in the range of 3 to 10 degrees. Magnetic layer 105 is within through glass via 142 and on a sidewall 113 of through glass via 142 such that sidewall 113 extends from front side 102 to back side 103 of glass core 101. As shown, magnetic layer 105 may be on an entirety of sidewall 113 such that magnetic layer 105 also extends from front side 102 to back side 103 of glass core 101. However, in some embodiments, portions of sidewall 113 may be exposed.

Inductor structure 104 further includes a metallization 106 that may include a conductive material layer 108 within through glass via 142 and on magnetic layer 105 (e.g., on a sidewall of magnetic layer 105). Metallization 106 may also include an interconnect 107 over front side 102 and an interconnect 109 over bottom size 103 of glass core 101. As used herein, terms such as top, bottom, over, etc. are used for the sake of clarity with respect to a particular orientation(s) of assembly 100. In particular, the term over may be used repeatedly with respect to several orientations. Notably, metallization 106 may be formed from several different metal components to provide a desired conductive path, routing, etc. For example, interconnects 107, 109 may be pads, lids, landings, routings, interconnect portions, or parts of such conductive components. In any event, conductive material layer 108 (which also may be characterized as metallization) within through glass via 142 and on magnetic layer 105 is contacted by other metallization. In some embodiments, such metallization may form an integrated structure lacking grain boundaries or the like. In other embodiments, the metallization may include other materials, grain boundaries, adhesion layers, etc. Metallization 106 and/or the subcomponents thereof may include any conductive materials or material stacks including copper, gold, aluminum, tungsten, etc. Herein, metallization 106 and the subcomponents thereof are typically described as being copper in accordance with some embodiments. However, other material(s) may be deployed.

As shown, in some embodiments, inductor structure 104 also includes an insulating material plug 110 within through glass via 142 and on conductive material layer 108 (e.g., on a sidewall of conductive material layer 108). Insulating material plug 110 may include any electrical insulator such as a non-conductive ink (e.g., a non-conductive dispersion of graphite in a thermoplastic resin or similar materials) or any electrically insulating material. In other embodiments, insulating material plug 110 and conductive material layer 108 extends across through glass via 142 to form a plug (e.g., having a substantially cylindrical shape when no taper is evident, or, when a taper is evident, being, substantially, a conical frustum). In other embodiments, insulating material plug 110 is not employed and conductive material layer 108 does extends across through glass via 142 to form a plug. In such embodiments, inductor structure 104 may include an air gap therein.

As discussed, inductor structure 104 includes magnetic layer 105 formed on sidewall 113 of through glass via 142. Magnetic layer 105 may have any suitable thickness (e.g., in the x-dimension), t, along sidewall 113 such as a thickness in the range of 5 to 25 μm. In some embodiments, magnetic layer 105 has a thickness in the range of 5 to 10 μm. In some embodiments, magnetic layer 105 has a thickness in the range of 10 to 15 μm. In some embodiments, magnetic layer 105 has a thickness in the range of 15 to 25 μm. In some embodiments, magnetic layer 105 has a thickness that is in the range of 15 to 30% of the width of through glass via 142. Herein, a thickness or other measures may be defined and measured at one location, a number (e.g., 3 to 10) measurements may be averaged, or other measurement techniques may be deployed.

In some embodiments, magnetic layer 105 is a solid or solid state material and is a metallic alloy of two or more metal or metalloid materials. As used herein the term solid or solid state with respect to a material indicates the material is structurally rigid and is not suspended in another material such as an epoxy, resin, or other matrix. Furthermore, the term magnetic indicates a material that has a relatively high permeability (e.g., relative permeability greater than 5,000) such that the material obtains magnetization in response to an applied magnetic field. Furthermore, magnetic layer 105 is a substantially pure inclusive of the two or more metal or metalloid materials. The term metal is used in its common meaning of a lustrous material that is conductive of heat and electricity and includes cobalt, iron, neodymium, niobium, and nickel. The term metalloid is used to indicate a material that shares metal and non-metal traits and includes boron. The alloy of such materials (inclusive of boron) may be characterized as a metal herein.

Magnetic layer 105 may include any alloy inclusive of one or more of cobalt (Co), iron (FE), neodymium (Nd), boron (B), niobium (Nb), and nickel (Ni). In some embodiments, magnetic layer 105 is an alloy of any two or more of cobalt (Co), iron (FE), neodymium (Nd), boron (B), niobium (Nb), and nickel (Ni). In some embodiments, magnetic layer 105 is an alloy of cobalt and iron (e.g., CoFe) such that it is not less than 99% pure CoFe. In some embodiments, magnetic layer 105 is an alloy of nickel and iron (e.g., NiFe) such that it is not less than 99% pure NiFe. In some embodiments, magnetic layer 105 is an alloy of neodymium, iron, boron, and cobalt (e.g., NdFeBCo) such that it is not less than 99% pure NdFeBCo. In some embodiments, magnetic layer 105 is an alloy of neodymium, iron, and boron (e.g., NdFeB) such that it is not less than 99% pure NdFeCo. In some embodiments, magnetic layer 105 is an alloy of niobium and iron (e.g., NbFe) such that it is not less than 99% pure NbFe. In some embodiments, magnetic layer 105 is an alloy of niobium, iron, and boron (e.g., NbFeB) such that it is not less than 99% pure NbFeB.

In some embodiments, magnetic layer 105 is a solid substantially pure metallic alloy of two or more metal or metalloid materials. In some embodiments, magnetic layer 105 is a solid substantially pure metallic alloy of two or more metal or metalloid magnetic materials including one or both being high-spin transition metals. In some embodiments, the two or more metal or metalloid materials include two or more of cobalt, iron, neodymium, boron, niobium, or nickel. the two or more metal or metalloid materials include iron and one or more of cobalt, nickel, neodymium, or niobium. In some embodiments, the two or more metal or metalloid materials include neodymium, iron, and boron. In some embodiments, the two or more metal or metalloid materials include neodymium, iron, boron, and cobalt. As discussed herein, in some embodiments, one or both of such metal or metalloid materials are deposited using supramolecular chemistry. In such embodiments, magnetic layer 105 may further include one or more atoms from the supramolecular chemistry inclusive of carbon, oxygen, and others. In some embodiments, magnetic layer 105 further includes carbon.

As discussed, inductor structure 104 further includes conductive material layer 108 formed on sidewall 113 of through glass via 142. Conductive material layer 108 may include any suitable conductive material or materials. In some embodiments, conductive material layer 108 includes copper. Conductive material layer 108 may have any suitable thickness (e.g., in the x-dimension) along sidewall 113 such as a thickness in the range of 5 to 25 μm. Inductor structure 104 may also include optional insulating material plug 110 within through glass via 142 and on conductive material layer 108. Insulating material plug 110 may have any suitable thickness (e.g., in the x-dimension) such as a thickness in the range of 5 to 25 μm.

As shown, assembly 100 further includes inductor structure 114 adjacent inductor structure 104. Inductor structures 104, 114 may be part of the same inductive element such that inductor structures 104, 114 are tethered together or electrically connected in series or they may be part of different inductive elements as illustrated herein below. Inductor structure 114 includes a magnetic layer 115, a conductive material layer 118, and optional insulating material plug 110. Magnetic layer 115 is within a through glass via (TGV) 143 formed in glass core 101 and extends from front side 102 to back side 103 thereof. Conductive material layer 118, which may be part of a metallization 116, is within through glass via 143 and on magnetic layer 115 and optional insulating material plug 120 is within through glass via 143 and on conductive material layer 118. Furthermore, metallization 116 may include interconnects 117, 119 such that conductive material layer 118 extends from interconnect 117 (which is over front side 102) to interconnect 119 (which is over back side 103).

The components of inductor structure 114 may have any characteristics discussed with respect to inductor structure 104. For example, through glass via 143 may have any characteristics discussed with respect to through glass via 142, magnetic layer 115 may have any characteristics discussed with respect to magnetic layer 105, conductive material layer 118 may have any characteristics discussed with respect to conductive material layer 108, and so on. Furthermore, such shared components may have the same or differing characteristics between inductor structures 104, 114.

Furthermore, FIG. 1 illustrates, in enlarged view 150, a portion of magnetic layer 105. As discussed, magnetic layer 105 may include an alloy of metal or metalloid materials. In some embodiments, the alloy includes multiple phases such as a first phase 121 and a second phase 122. Furthermore, the phases may form, in a self-assembled fashion such that second phase 122 is embedded within first phase 121 with first phase 121 being at sidewall 113 (e.g., at the interface of magnetic layer 105 and the glass of glass core 101. Furthermore, first phase 121 may be at an outer surface 124 of magnetic layer 105 with little or none of second phase 122 being exposed at outer surface 124. Such multiple phases may be evident in any material combination discussed herein with first phase 121 being rich in one of the metal or metalloid materials and second phase 122 being rich in another of the metal or metalloid materials.

In particular, enlarged view 150 illustrates an example magnetic layer 105 of cobalt and nickel where first phase 121 is rich in nickel (e.g., first phase 121 is a nickel phase) and second phase 122 is rich in cobalt (e.g., second phase 122 is a nickel phase). In some embodiments, additional phases are evident in magnetic layer 105. In some embodiments, the number of phases in magnetic layer 105 is the same as the number of employed metal or metalloid materials. However, fewer, or no distinct phases may be evident in magnetic layer 105. Furthermore, enlarged view 150 illustrates outer surface 124 of magnetic layer 105 may have a relatively unsmooth surface including ridges, valleys, etc. due to the techniques used to form magnetic layer 105.

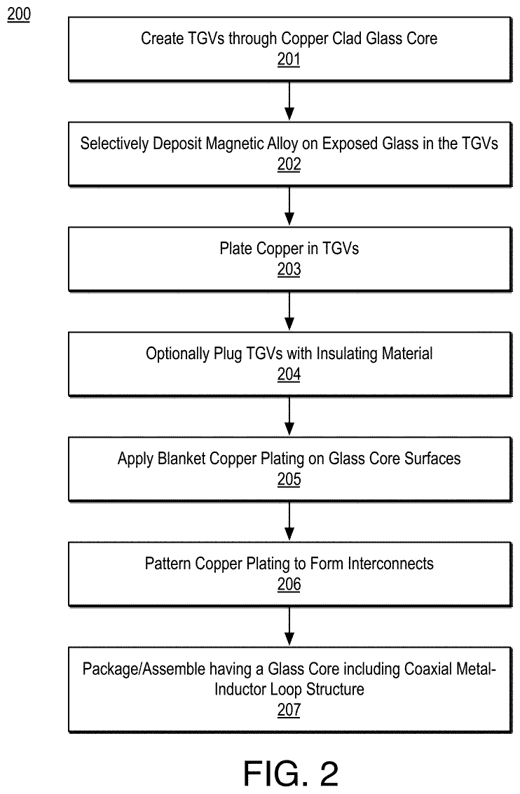

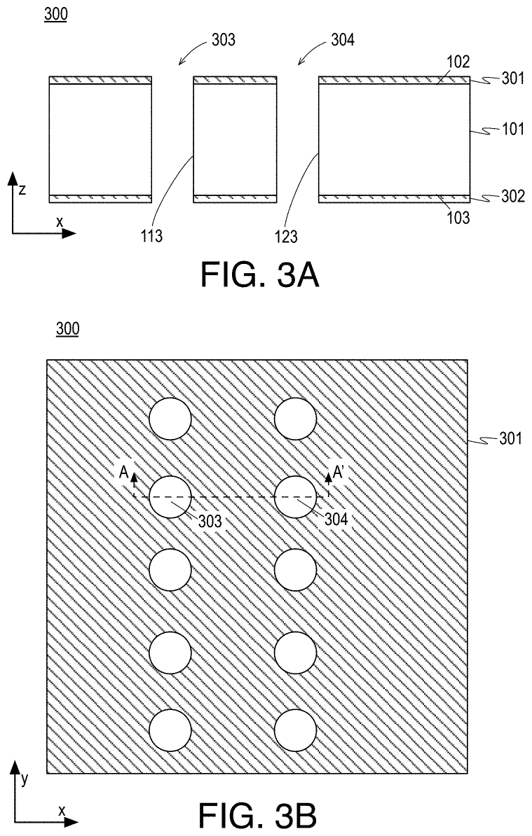

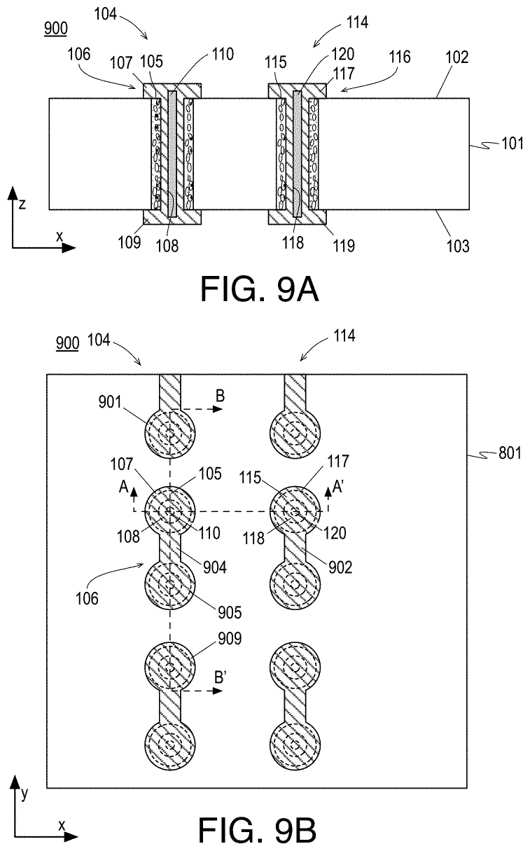

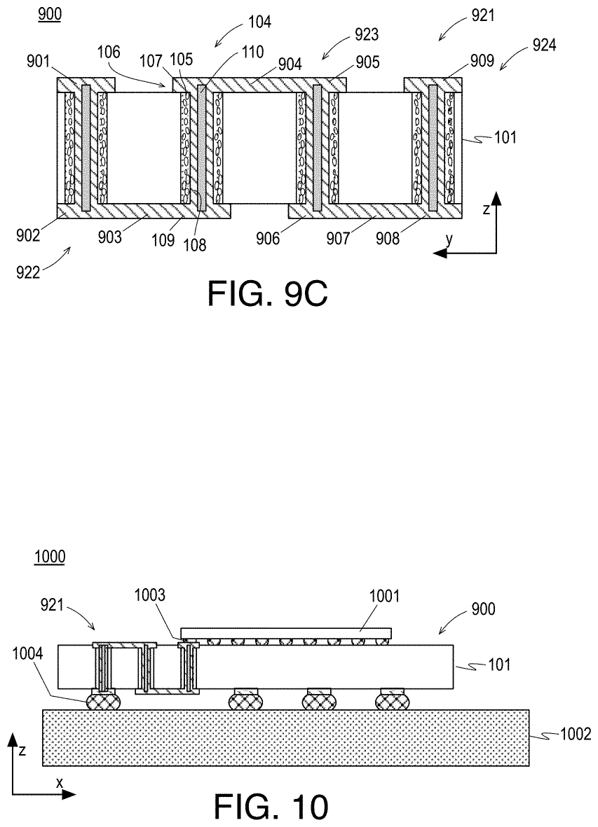

FIG. 2 illustrates a flow diagram of an example process 200 for fabricating coaxial metal-inductor loop structures in a glass core substrate, arranged in accordance with at least some implementations of the present disclosure. For example, process 200 may be implemented to fabricate assembly 100, glass core package substrate 141, inductor structures 104, 114, and/or any other inductor structure discussed herein. In the illustrated implementation, process 200 may include one or more operations as illustrated by operations 201-207. However, embodiments herein may include additional operations, certain operations being omitted, or operations being performed out of the order provided. FIGS. 3A, 4A, 6A, 7A, 8A, 9A, and 10 illustrate cross-sectional side views of example assembly structures as particular fabrication operations in FIG. 2 are performed, arranged in accordance with at least some implementations of the present disclosure. FIGS. 3B, 4B, 6B, 7B, 8B, and 9B illustrate top-down views of the example assembly structures of FIGS. 3A, 4A, 6A, 7A, 8A, and 9A, arranged in accordance with at least some implementations of the present disclosure. FIG. 9C illustrates a second cross-sectional side view of the example assembly structure of FIGS. 9A and 9B, arranged in accordance with at least some implementations of the present disclosure. FIG. 5 illustrates an exemplary deposition of a magnetic alloy on exposed glass in a through glass via, arranged in accordance with at least some implementations of the present disclosure.

With reference to FIG. 2, process 200 begins at operation 201, where a copper clad glass core package substrate is received for processing and any number of through glass vias are formed in the copper clad glass core package substrate. Although discussed herein with respect to copper for the sake of clarity of presentation, the glass core package substrate may be clad in any material that will provide selective deposition of a magnetic alloy onto glass but not onto the cladding at operation 202 as discussed below. In some embodiments, conductor such as a metal is employed such that, at later operations, the cladding may be incorporated into the final coaxial metal-inductor loop structure. However, in other embodiments, the cladding may be fully removed after being used as a mask for the selective deposition of the magnetic alloy onto glass. In some embodiments, the cladding is copper, as discussed. In some embodiments, the cladding is one of aluminum, gold, tungsten, or other metal. In some embodiments, the cladding is a polymeric material such as an epoxy resin, a resist material, or a hardmask material.

The through glass vias may be formed in the clad glass core package substrate using any suitable technique or techniques. In some embodiments, the through glass vias are formed using laser ablation techniques. In some embodiments, the through glass vias are formed using patterning and wet etch techniques. In any case, the glass sidewalls of the through glass vias are exposed while the front and back sides of the glass core substrate are covered by the cladding thereon (e.g., copper cladding). Such surface differentiation provides for selective deposition of a magnetic alloy material.

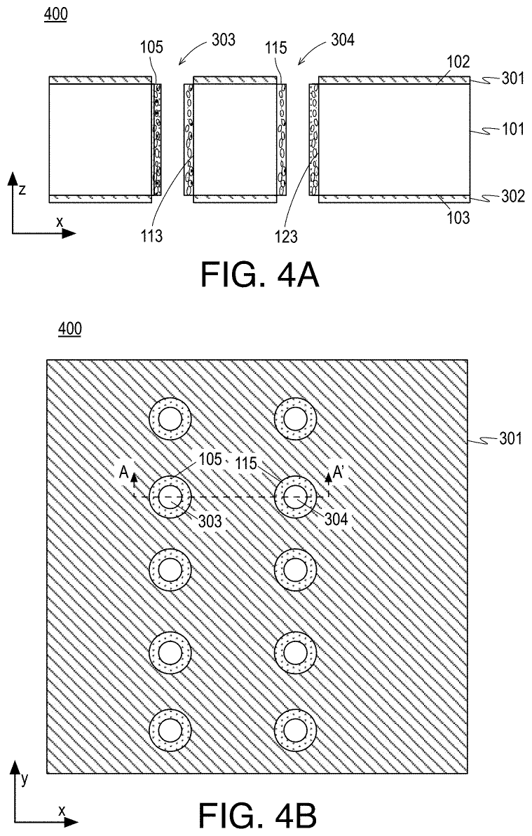

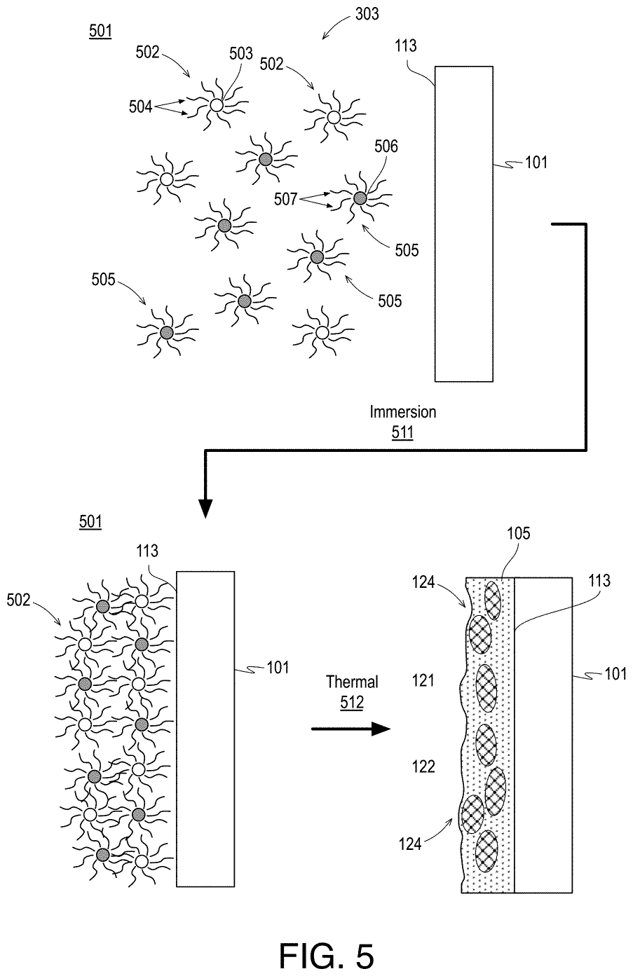

FIG. 3A and 3B illustrate an example assembly structure 300 after forming through glass vias in a clad glass package core. In FIG. 3A, a cross-sectional side view is illustrated as taken along the A-A′ plane shown in the top-down view of FIG. 3B. The top-down view illustrates a portion of a package substrate for example. The same views are shown in FIGS. 4A and 4B, 6A and 6B, 7A and 7B, 7A and 7B, 8A and 8B, and 9A and 9B, with an additional cross-sectional side view shown in FIG. 9C.

As shown, glass core 101, including a metallic cladding on front side 102 and a metallic cladding on back side 103, opposite front side 102, is received for processing. A number of through glass vias, inclusive of through glass vias 303, 304, are formed in the metallic claddings and glass core 101 to provide assembly structure 300 having a patterned metallic cladding 301 on front side 102 and a patterned metallic cladding 302 on back side 103. For example, through glass vias 303, 304 extend from patterned metallic cladding 301 to patterned metallic cladding 302. Furthermore, through glass vias 303, 304 expose glass sidewalls 113, 123 of glass core 101.

Through glass vias 303, 304 may also have any suitable widths (e.g., diameter critical dimensions) such as widths in the range of 20 to 200 μm. Each of the through glass vias 303, 304 may have the same width or they may be different. Furthermore, in some embodiments, through glass vias 303, 304 have a substantially cylindrical shapes and, in other embodiments, through glass vias 303, 304 may be tapered due to the method used to form them.

Returning to FIG. 2, processing continues at operation 202, where a magnetic alloy material is selectively deposited on the exposed glass in the through glass vias. For example, the sidewall of each through glass via is selectively coated with a magnetic layer eluding a solid substantially pure metallic alloy of two or more metal or metalloid materials. The deposited magnetic alloy material may have any characteristics discussed herein with respect to magnetic layers 105, 115 or elsewhere herein. For example, the deposited magnetic alloy material may have a thickness from the sidewall in the range of 5 to 25 μm and the deposited magnetic alloy material may cover the exposed sidewalls of the through glass vias. The deposited magnetic alloy material is a solid substantially pure metallic alloy of two or more metal or metalloid materials. In some embodiments, the two or more metal or metalloid materials including two or more of cobalt, iron, neodymium, boron, niobium, and nickel.

The magnetic alloy material is deposited using wet-deposition techniques using magnetic supramolecular precursors to form a self-assembled film. The magnetic supramolecular precursors or coordination complexes form selectively on the exposed glass relative to the cladding (e.g., copper or other material that repels the magnetic supramolecular precursors) as the magnetic supramolecular precursors are drawn to the exposed glass. The magnetic supramolecular precursors include a central atom of the magnetic alloy (e.g., a cobalt, iron, neodymium, boron, niobium, or nickel atom) surrounded by any number of ligands. The ligands may be any suitable molecule that coordinates with the high-spin transition metal atom (e.g., a cobalt, iron, neodymium, boron, niobium, or nickel atom) and provides selective attraction to the exposed glass.

In some embodiments, the ligand includes an outward facing (i.e., away from the central metal atom) hydrophobic group or molecule portion to selectively stick, adhere, or be drawn to the exposed glass and an inward facing (i.e., toward the central metal atom) hydrophilic group or molecule portion to be drawn to the central metal atom. In some embodiments, the inward facing hydrophilic group or molecule guards the central metal atom during adherence to the exposed glass. In some embodiments, the ligand is an alkyl chain molecule (e.g., a CH2 chain). In some embodiments, the ligand is an alkoxy chain molecule (e.g., a CH2 chain including O in the chain).

In some embodiments, the outward facing hydrophobic group or molecule portion has a terminating end that terminates at a methyl group (e.g., CH3). In some embodiments, the outward facing hydrophobic group or molecule portion has a terminating end that terminates at a siloxane group (e.g., SiO2 or any group with an Si—O—Si linkage or derived from an organosilicon group). In some embodiments, the inward facing hydrophilic group or molecule portion has a terminating end that terminates at an amine group (e.g., an NH2 group). In some embodiments, the inward facing hydrophilic group or molecule portion has a terminating end that terminates at an amino group. In some embodiments, the inward facing hydrophilic group or molecule portion has a terminating end that terminates at a carboxylic acid group (e.g., C(═O)OH). In some embodiments, the ligand is ethylenediamine.

FIG. 4A and 4B illustrate an example assembly structure 400 similar to assembly structure 300 after selective coating sidewalls 113, 123 with magnetic layers 105, 115, respectively such that magnetic layers 105, 115 are solid substantially pure metallic alloys of two or more metal or metalloid materials. As shown, magnetic layers 105, 115 are formed selectively on the exposed glass of sidewalls 113, 123 in through glass vias such that and magnetic layers 105, 115 substantially covers the entireties of sidewalls 113, 123 and little or no magnetic material is formed on patterned metallic claddings 301, 302. Magnetic layers 105, 115 may have any characteristics discussed herein. In some embodiments, magnetic layers 105, 115 include two or more of cobalt, iron, neodymium, boron, niobium, and nickel. Magnetic layer 105 may have any suitable thickness such as a thickness in the range of 5 to 25 μm.

FIG. 5 illustrates exemplary deposition of magnetic layer 115 on exposed glass of sidewall 113 in through glass via 303 inclusive of immersing glass core 101 in a wet-deposition 501 having a solution or mixture including two or more magnetic supramolecular precursor types including, for example, magnetic supramolecular precursors 502 and magnetic supramolecular precursors 505. As shown, magnetic supramolecular precursors 502 includes a central high spin magnetic atom 503 such as cobalt, iron, neodymium, boron, niobium, or nickel surrounded by a number of ligands 504. Similarly, magnetic supramolecular precursors 505 includes a central high spin magnetic atom 506 such as another cobalt, iron, neodymium, boron, niobium, or nickel surrounded by a number of ligands 507. Ligands 504 and ligands 507 may be the same or they may be different. Although illustrated with respect to two magnetic supramolecular precursors 502, 505, a number of magnetic supramolecular precursors equal to the number of magnetic atoms in the resultant magnetic alloy of magnetic layer 105 may be used.

Ligands 504, 507 may be any suitable molecule that coordinates with central high spin magnetic atoms 503, 506, respectively, to provides selective attraction to the exposed glass of sidewall 113 of glass core 101 relative to patterned metallic claddings 301, 302 (not shown in FIG. 5). In some embodiments, ligands 504, 507 include an outward facing hydrophobic group or molecule portion to selectively adhere the exposed glass of glass core 101 and an inward facing hydrophilic group or molecule portion to be drawn to central high spin magnetic atoms 503, 506. In some embodiments, one or both of ligands 504, 507 is an alkyl chain molecule or an alkoxy chain molecule (e.g., a CH2 chain including O in the chain). In some embodiments, the outward facing hydrophobic group of one or both of ligands 504, 507 has a terminating end that terminates at a methyl group or a siloxane group. In some embodiments, the inward facing hydrophilic group of one or both of ligands 504, 507 has a terminating end that terminates at an amine group, an amino group, or a carboxylic acid group. In some embodiments, one or both of ligands 504, 507 is ethylenediamine.

As shown with respect to immersion operation 511, magnetic supramolecular precursors 502, 505 self assemble at glass sidewall 113 due to the affinity of the outfacing ends of ligands 504, 507 to glass sidewall 113. That is, ligands 504, 507 coordinate with high-spin transition metals (i.e., central high spin magnetic atoms 503, 506) and attract to the glass of sidewall 113 of glass core 101. Subsequently, thermal processing is performed as indicated with respect to thermal operation 512 (e.g., an application of heat) to form the high-permeability magnetic layer 105 having any characteristics as discussed herein. Thermal operation 512 may be performed at any suitable temperature such as a temperature in the range of 275° C. to 350° C. with 300° C. being particularly advantageous.

Returning to FIG. 2, processing continues at operation 203, where copper or other conductive material is plated within the through glass via and on the exposed sidewall of the magnetic alloy as well as on the cladding on the top and bottom surfaces of the glass package core. Although illustrated with respect to copper plating, other conductive material(s) and processes may be deployed. For example, the conductive material may be one or more of aluminum, gold, tungsten, or other metal. The deposition operation provides a conductor layer on the magnetic layer and within the through glass via, as part of an eventual coaxial metal-inductor loop structure.

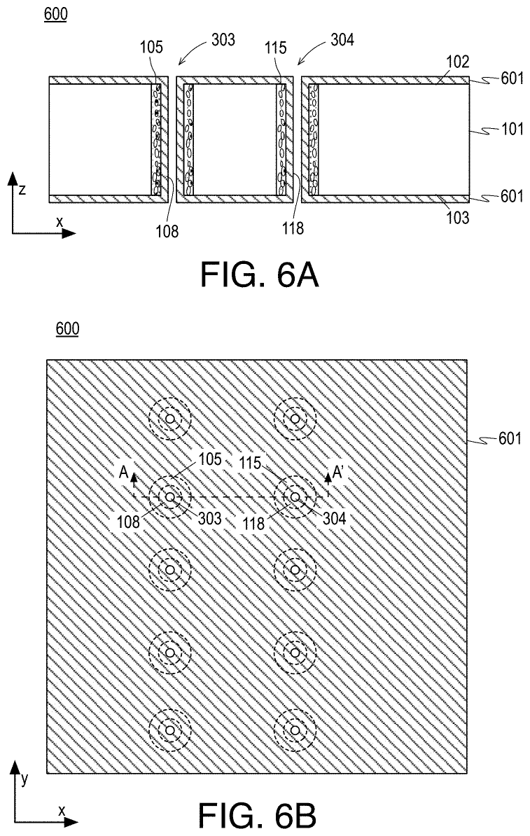

FIG. 6A and 6B illustrate an example assembly structure 600 similar to assembly structure 400 after deposition of conformal conductive layer 601. As shown, conductive layer 601 (e.g., a copper layer) is formed in a substantially conformal manner over exposed portions of assembly structure 400 inclusive of magnetic layers 105, 115 and patterned metallic claddings 301, 302. For example, conductive layer 601, as shown, may include portions of patterned metallic claddings 301, 302 as an integrated metallization. Conductive layer 601 may be formed using any suitable technique or techniques such electroplating techniques. In the top-down view of FIG. 6B and in subsequent top-down views, buried structures are illustrated in dashed lines for the sake of clarity of presentation.

Returning to FIG. 2, processing continues at operation 204, where the through glass vias are optionally plugged with an insulating material. The plug may be any insulating material such as a non-conductive ink (e.g., a non-conductive dispersion of graphite in a thermoplastic resin or similar materials) or any electrically insulating material. The plug may be formed using any suitable technique or techniques such as local dispense techniques and optional smoothing or planarizing techniques. In some embodiments, no plug material is provided. In some embodiments, at operation 204, the conductive material fills the through glass via in a similar manner as a plated through hole.

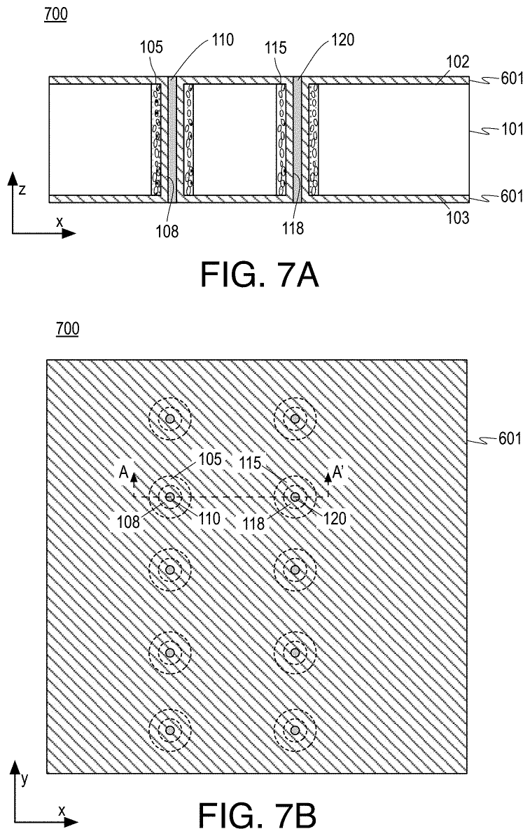

FIG. 7A and 7B illustrate an example assembly structure 700 similar to assembly structure 400 after insulating material plugs 110, 120 are formed in the remainder of through glass vias 303, 304. Insulating material plugs 110, 120 may have any characteristics discussed herein. For example, insulating material plugs 110, 120 include a non-conductive ink having a thickness in the range of 5 to 25 μm.

Returning to FIG. 2, processing continues at operation 205, where copper or other conductive material is blanked plated on the opposing sides of the glass core assembly. Although illustrated with respect to copper plating, other conductive material(s) and processes may be deployed. For example, the conductive material may be one or more of aluminum, gold, tungsten, or other metal. The deposition operation provides a conductor layer on the sides of the glass core assembly for the formation of conductive interconnects.

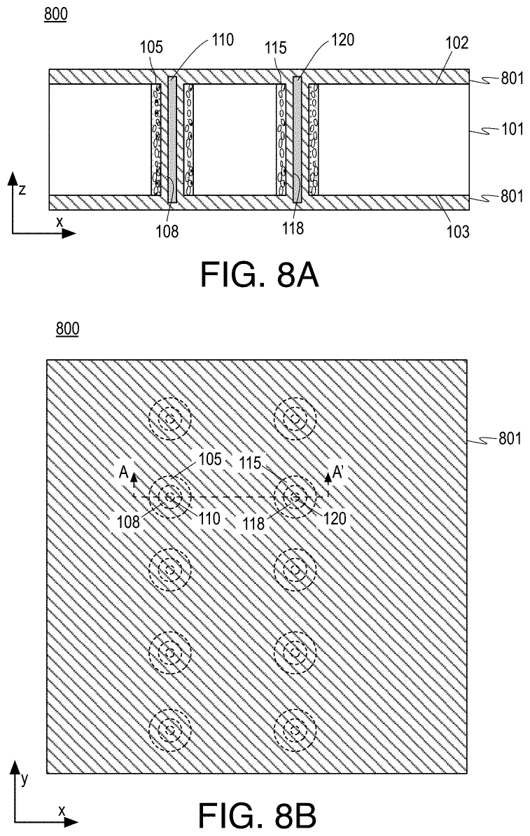

FIG. 8A and 8B illustrate an example assembly structure 800 similar to assembly structure 700 after deposition of conductive layer 801. As shown, conductive layer 801 (e.g., a copper layer) is formed in a substantially conformal manner over exposed portions of assembly structure 700 inclusive of exposed portions of insulating material plugs 110, 120 and conductive layer 601. For example, conductive layer 801, as shown, may include portions of prior applied conductive materials (e.g., copper) as an integrated metallization. Conductive layer 801 may be formed using any suitable technique or techniques such electroplating techniques.

Returning to FIG. 2, processing continues at operation 206, where the copper plating is patterned to form interconnects over the front side and back side surfaces of the glass core substrate. The interconnects may include any suitable interconnect structures such as lids, landing pads, conductive routing, and so on. The interconnects may be formed using any suitable technique or techniques such as patterning and subtractive etch techniques.

FIG. 9A, 9B, and 9C illustrate an example assembly structure 900 similar to assembly structure 800 after patterning conductive layer 801 to form interconnects such as conductive interconnects. In FIG. 9C, a cross-sectional side view is illustrated as taken along the B-B′ plane shown in the top-down view of FIG. 9B. As shown, conductive layer 801 is patterned to form metallization 106, inclusive of interconnect 107 (e.g., a lid or pad), conductive material layer 108 (e.g., the metal portion of a coaxial metal-inductor loop structure), and interconnect 109 (e.g., a lid or pad), and metallization 116, inclusive of interconnect 117 (e.g., a lid or pad), conductive material layer 118 (e.g., the metal portion of a coaxial metal-inductor loop structure), and interconnect 119 (e.g., a lid or pad). Metallizations 106, 116 and the sub-components thereof may include any characteristics discussed herein.

Furthermore, as shown with respect to FIG. 9C, inductor structure 104 may include a number of tethered coaxial metal-inductor loop structures 921 (e.g., coaxial metal-inductor loop structures being connected in series). For example, each coaxial metal-inductor loop structure may include a magnetic layer on a sidewall of a through glass via, a conductive material layer on the magnetic layer, and an optional insulating plug. In the illustrated example, metallization of tethered coaxial metal-inductor loop structures 921 includes a front side interconnect 901 in contact with the conductive material layer (not labeled) of inductor structure 922, which is in contact with back side interconnect 902. Similarly, interconnect 109 is in contact with conductive material layer 108, which, in turn, is in contact with interconnect 107. As with inductor structure 922, inductor structure 923 includes a front side interconnect 905 in contact with the conductive material layer (not labeled) of inductor structure 923, which is in contact with back side interconnect 906. Similarly, inductor structure 924 includes a front side interconnect 909 in contact with the conductive material layer (not labeled) of inductor structure 924, which is in contact with back side interconnect 908.

As shown, tethered coaxial metal-inductor loop structures 921 are interconnected by interconnect traces 903, 904, 907, and so on such that back side interconnect 902 is in contact with interconnect 109 (e.g., a back side interconnect) via an interconnect trace 903 (e.g., to connect inductor structures 922, 104), interconnect 107 (e.g., a front side interconnect) is in contact with front side interconnect 905 via an interconnect trace 904 (e.g., to connect inductor structures 104, 923), back side interconnect 906 is in contact with back side interconnect 908 (e.g., to connect inductor structures 923, 924), and so on. Inductor structure 114 may be similarly tethered to other inductor structures and/or to inductor structure 104 using such interconnect trace.

The illustrated process flow provides an assembly including a glass core package having inductor structures formed in through glass vias therein. Other devices or structures may also be formed in other through glass vias and/or on surfaces of the glass core package. The glass core package assembly may be incorporated into any suitable package. In some embodiments, metallization layers for signal and power routing may be formed on one or both sides of the glass core package (e.g., redistribution layers). In some embodiments, one or more IC dies are mounted on one or both sides of the glass core package and coupled to one or more of the inductor structures discussed herein for power delivery to the IC die(s). In some embodiments, the glass core package may be employed as an interposer. In some embodiments, the glass core package may be mounted to an printed circuit board. Other configurations are available.

As shown, processing continues at operation 207, where the glass core including coaxial metal-inductor loop structures as discussed herein is assembled into a package or otherwise incorporated into a device. In some embodiments, a system includes an integrated circuit (IC) package coupled to a printed circuit board such that the IC package includes coaxial metal-inductor loop structure(s) in a glass core as discussed herein and an IC die is attached to the glass core and coupled to the coaxial metal-inductor loop structure(s), and a power supply attached to the printed circuit board and coupled to the IC die.

For example, an IC die may be mounted on a glass core including a coaxial metal-inductor loop structure as discussed herein such that the IC die is coupled to the coaxial metal-inductor loop structure for power delivery. The resultant assembly or package may then be attached to a printed circuit board or other substrate. The printed circuit board or other substrate may also host a power supply attached thereto, which is coupled to the IC die via the coaxial metal-inductor loop structure.

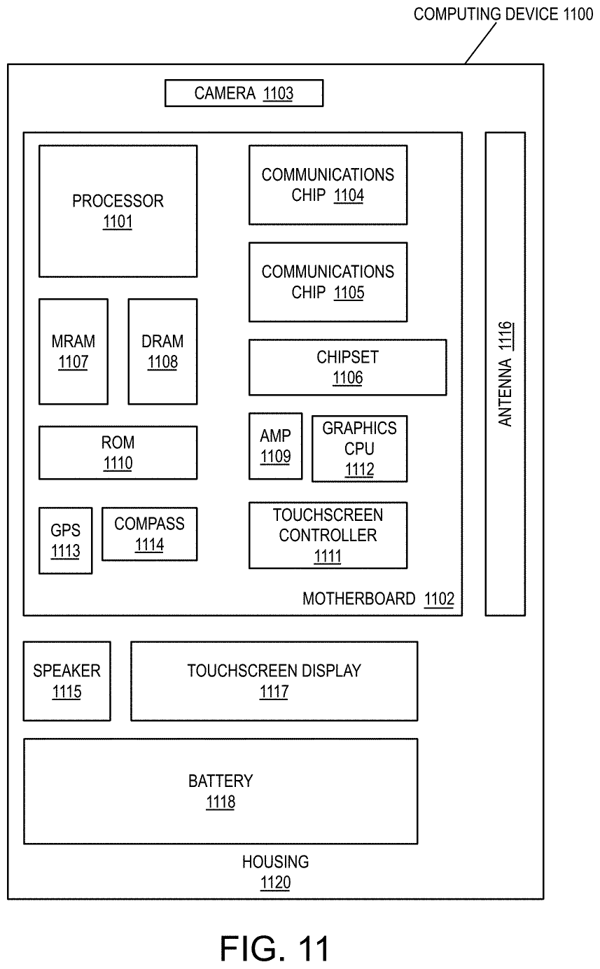

FIG. 10 illustrate an example system 1000 similar to assembly structure 900 after mounting an IC die 1001 on assembly structure 900 and coupling assembly structure 900 to a printed circuit board 1002. IC die 1001 may be coupled to assembly structure 900 using any suitable technique or techniques. Although illustrated with respect to attachment and coupling using a ball grid array 1003, IC die 1001 may be attached to assembly structure 900 using any suitable technique or techniques such as wire bonding, field grid arrays, etc. As shown, one or more balls of ball grid array 1003 may provide routing for power delivery to IC die 1001 via tethered coaxial metal-inductor loop structures 921 (with three tethered inductor structures being illustrated for the sake of clarity). Furthermore, assembly structure 900 may be coupled to printed circuit board 1002 using any suitable technique or techniques such as solder ball joints 1004 (as shown), as wire bonding, bond pads, and the like.

FIG. 11 is a functional block diagram of an electronic or computing device 1100, arranged in accordance with at least some implementations of the present disclosure. Electronic computing device 1100, in any component therein, may employ coaxial metal-inductor loop structures in a glass core substrate as described herein. Computing device 1100 may be found inside a platform or a server machine, for example, and may computing device 1100 may be provided in any suitable form factor device. In various implementations, computing device 1100 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, computing device 1100 may be any other electronic device that processes data.

As shown, computing device 1100 may include a housing 1120 and a motherboard 1102 therein hosting a number of components, such as, but not limited to, a processor 1101 (e.g., an applications processor). Processor 1101 may be physically and/or electrically coupled to motherboard 1102. In some embodiments, motherboard 1102 includes a via plug resistor and/or a via plug capacitor as discussed herein. In some examples, processor 1101 includes an integrated circuit die packaged within the processor 1101. In general, the term “processor” or “microprocessor” may refer to any device or portion of a device that processes electronic data from registers and/or memory to transform that electronic data into other electronic data that may be further stored in registers and/or memory.

In various examples, one or more communication chips 1104, 1105 may also be physically and/or electrically coupled to the motherboard 1102. In further implementations, communication chips 1104, 1105 may be part of processor 1101. Depending on its applications, computing device 1100 may include other components that may or may not be physically and electrically coupled to motherboard 1102. These other components include, but are not limited to, volatile memory (e.g., MRAM 1107, DRAM 1108), non-volatile memory (e.g., ROM 1110), flash memory, a graphics processor 1112, a digital signal processor, a crypto processor, a chipset 1106, an antenna 1116, touchscreen display 1117, touchscreen controller 1111, battery 1118, audio codec, video codec, power amplifier 1109, global positioning system (GPS) device 1113, compass 1114, accelerometer, gyroscope, audio speaker 1115, camera 1103, and mass storage device (such as hard disk drive, solid-state drive (SSD), compact disk (CD), digital versatile disk (DVD), and so forth), or the like.

Communication chips 1104, 1105 may enable wireless communications for the transfer of data to and from the computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1104, 1105 may implement any of a number of wireless standards or protocols, including but not limited to those described elsewhere herein. As discussed, computing device 1100 may include a plurality of communication chips 1104, 1105. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

In an embodiment, at least one of the integrated circuit components of computing device 1100 includes an electronic substrate having a via plug resistor and/or a via plug capacitor as discussed herein.

As used in any implementation described herein, the term “module” refers to any combination of software, firmware and/or hardware configured to provide the functionality described herein. The software may be embodied as a software package, code and/or instruction set or instructions, and “hardware”, as used in any implementation described herein, may include, for example, singly or in any combination, hardwired circuitry, programmable circuitry, state machine circuitry, and/or firmware that stores instructions executed by programmable circuitry. The modules may, collectively or individually, be embodied as circuitry that forms part of a larger system, for example, an integrated circuit (IC), system on-chip (SoC), and so forth.

The term “processor” may refer to any device or portion of a device that processes electronic data from registers and/or memory to transform that electronic data into other electronic data that may be stored in registers and/or memory.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

In one or more first embodiments, an apparatus comprises an integrated circuit package substrate comprising a glass core, a through glass via comprising a sidewall surface extending from a first side of the glass core to a second side of the glass core opposite the first side, a magnetic layer within the through glass via and on the sidewall surface of the glass core, the magnetic layer comprising a solid substantially pure metallic alloy of two or more metal or metalloid materials, and a conductive material within the through glass via and on the magnetic layer, the conductive material extending from a first interconnect over the first side of the glass core to a second interconnect over the first side of the glass core.

In one or more second embodiments, further to the first embodiment, the two or more metal or metalloid materials comprise two or more of cobalt, iron, neodymium, boron, niobium, or nickel.

In one or more third embodiments, further to the first or second embodiments, the magnetic layer further comprises carbon.

In one or more fourth embodiments, further to any of the first through third embodiments, the two or more metal or metalloid materials comprise iron and one or more of cobalt, nickel, neodymium, or niobium.

In one or more fifth embodiments, further to any of the first through fourth embodiments, the two or more metal or metalloid materials comprise neodymium, iron, and boron.

In one or more sixth embodiments, further to any of the first through fifth embodiments, the two or more metal or metalloid materials further comprise cobalt.

In one or more seventh embodiments, further to any of the first through sixth embodiments, the magnetic layer and the conductive material fill the through glass via.

In one or more eighth embodiments, further to any of the first through seventh embodiments, the apparatus further comprises an insulating material plug within the through glass via and on the conductive material.

In one or more ninth embodiments, further to any of the first through eighth embodiments, the apparatus further comprises an integrated circuit die on the package substrate and coupled to an inductor comprising the magnetic layer and the conductive material.

In one or more tenth embodiments, a system comprises an integrated circuit (IC) package coupled to a printed circuit board, the IC package comprising a package substrate comprising a glass core, a through glass via comprising a sidewall surface extending from a first side of the glass core to a second side of the glass core opposite the first side, a magnetic layer within the through glass via and on the sidewall surface of the glass core, the magnetic layer comprising a solid substantially pure metallic alloy of two or more metal or metalloid materials, a conductive material within the through glass via and on the magnetic layer, the conductive material extending from a first interconnect over the first side of the glass core to a second interconnect over the first side of the glass core, and an IC die attached to the glass core and coupled to an inductor comprising the magnetic layer and the conductive material, and a power supply attached to the printed circuit board and coupled to the IC die.

In one or more eleventh embodiments, further to the tenth embodiment, the two or more metal or metalloid materials comprise two or more of cobalt, iron, neodymium, boron, niobium, or nickel.

In one or more twelfth embodiments, further to the tenth or eleventh embodiments, the two or more metal or metalloid materials comprise iron and one or more of cobalt, nickel, neodymium, or niobium.

In one or more thirteenth embodiments, further to any of the tenth through tenth embodiments, the two or more metal or metalloid materials comprise neodymium, iron, and boron.

In one or more fourteenth embodiments, a method comprises receiving a glass core package substrate, the glass core package substrate comprising a first side and a second side opposite the first side, the first side comprising a first metallic cladding thereon and a the second side comprising a second metallic cladding thereon, forming a through glass via in the glass core package substrate, the through glass via comprising a sidewall surface of the glass core package substrate extending from the first metallic cladding to the second metallic cladding, selectively coating the sidewall surface of the through glass via with a magnetic layer comprising a solid substantially pure metallic alloy of two or more metal or metalloid materials, and forming a conductive material within the through glass via and on the magnetic layer.

In one or more fifteenth embodiments, further to the fourteenth embodiment, selectively coating the sidewall surface of the through glass via with the magnetic layer comprises immersing the glass core in a solution comprising a first coordination complex comprising a first metal atom surrounded by a plurality of first ligands and a second coordination complex comprising a second metal atom surrounded by a plurality of second ligands to coat the sidewall surface of the through glass via with the first and second coordination complexes and heat treating the coated glass core.

In one or more sixteenth embodiments, further to the fourteenth or fifteenth embodiments, the first ligands comprise a alkyl chain comprising a hydrophilic group proximal the first metal atom and a hydrophobic group distal the first metal atom.

In one or more seventeenth embodiments, further to any of the fourteenth through sixteenth embodiments, said heat treating comprises heat treatment at a temperature of not less than 300° C.

In one or more eighteenth embodiments, further to any of the fourteenth through seventeenth embodiments, selectively coating the sidewall surface of the through glass via with the magnetic layer comprises electroless deposition of the magnetic layer.

In one or more nineteenth embodiments, further to any of the fourteenth through eighteenth embodiments, the two or more metal or metalloid materials comprise two or more of cobalt, iron, neodymium, boron, niobium, or nickel.

In one or more twentieth embodiments, further to any of the fourteenth through nineteenth embodiments, the two or more metal or metalloid materials comprise iron and one or more of cobalt, nickel, neodymium, or niobium.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An apparatus comprising:
an integrated circuit package substrate comprising a glass core;
a through glass via comprising a sidewall surface extending from a first side of the glass core to a second side of the glass core opposite the first side;
a magnetic layer within the through glass via and on the sidewall surface of the glass core, the magnetic layer comprising a solid substantially pure metallic alloy of two or more metal or metalloid materials; and
a conductive material within the through glass via and on the magnetic layer, the conductive material extending from a first interconnect over the first side of the glass core to a second interconnect over the first side of the glass core.

2. The apparatus of claim 1, wherein the two or more metal or metalloid materials comprise two or more of cobalt, iron, neodymium, boron, niobium, or nickel.

3. The apparatus of claim 2, wherein the magnetic layer further comprises carbon.

4. The apparatus of claim 1, wherein the two or more metal or metalloid materials comprise iron and one or more of cobalt, nickel, neodymium, or niobium.

5. The apparatus of claim 1, wherein the two or more metal or metalloid materials comprise neodymium, iron, and boron.

6. The apparatus of claim 5, wherein the two or more metal or metalloid materials further comprise cobalt.

7. The apparatus of claim 1, wherein the magnetic layer and the conductive material fill the through glass via.

8. The apparatus of claim 1, further comprising:
an insulating material plug within the through glass via and on the conductive material.

9. The apparatus of claim 1, further comprising:
an integrated circuit die on the package substrate and coupled to an inductor comprising the magnetic layer and the conductive material.

10. A system comprising:
an integrated circuit (IC) package coupled to a printed circuit board, the IC package comprising:
a package substrate comprising a glass core;
a through glass via comprising a sidewall surface extending from a first side of the glass core to a second side of the glass core opposite the first side;
a magnetic layer within the through glass via and on the sidewall surface of the glass core, the magnetic layer comprising a solid substantially pure metallic alloy of two or more metal or metalloid materials;
a conductive material within the through glass via and on the magnetic layer, the conductive material extending from a first interconnect over the first side of the glass core to a second interconnect over the first side of the glass core; and
an IC die attached to the glass core and coupled to an inductor comprising the magnetic layer and the conductive material; and
a power supply attached to the printed circuit board and coupled to the IC die.

11. The electronic system of claim 10, wherein the two or more metal or metalloid materials comprise two or more of cobalt, iron, neodymium, boron, niobium, or nickel.

12. The electronic system of claim 10, wherein the two or more metal or metalloid materials comprise iron and one or more of cobalt, nickel, neodymium, or niobium.

13. The electronic system of claim 10, wherein the two or more metal or metalloid materials comprise neodymium, iron, and boron.

14. A method comprising:
receiving a glass core package substrate, the glass core package substrate comprising a first side and a second side opposite the first side, the first side comprising a first metallic cladding thereon and a the second side comprising a second metallic cladding thereon;
forming a through glass via in the glass core package substrate, the through glass via comprising a sidewall surface of the glass core package substrate extending from the first metallic cladding to the second metallic cladding;
selectively coating the sidewall surface of the through glass via with a magnetic layer comprising a solid substantially pure metallic alloy of two or more metal or metalloid materials; and
forming a conductive material within the through glass via and on the magnetic layer.

15. The method of claim 14, wherein selectively coating the sidewall surface of the through glass via with the magnetic layer comprises:
immersing the glass core in a solution comprising a first coordination complex comprising a first metal atom surrounded by a plurality of first ligands and a second coordination complex comprising a second metal atom surrounded by a plurality of second ligands to coat the sidewall surface of the through glass via with the first and second coordination complexes; and
heat treating the coated glass core.

16. The method of claim 15, wherein the first ligands comprise a alkyl chain comprising a hydrophilic group proximal the first metal atom and a hydrophobic group distal the first metal atom.

17. The method of claim 15, wherein said heat treating comprises heat treatment at a temperature of not less than 300° C.

18. The method of claim 14, wherein selectively coating the sidewall surface of the through glass via with the magnetic layer comprises electroless deposition of the magnetic layer.

19. The method of claim 14, wherein the two or more metal or metalloid materials comprise two or more of cobalt, iron, neodymium, boron, niobium, or nickel.

20. The method of claim 14, wherein the two or more metal or metalloid materials comprise iron and one or more of cobalt, nickel, neodymium, or niobium.
